(19) United States
(12) Patent Application Publication
(10) Pub. No.: US 2014/0319565 A1
(43) Pub. Date: Oct. 30, 2014

(54) LIGHT EMITTING DIODE PACKAGE

(71) Applicant: ADVANCED OPTOELECTRONIC TECHNOLOGY, INC., Hsinchu Hsien (TW)

(72) Inventors: CHE-HSANG HUANG, Hukou (TW); HSIN-CHIANG LIN, Hukou (TW); FU-HSIANG YEH, Hsinchu (TW)

(73) Assignee: ADVANCED OPTOELECTRONIC TECHNOLOGY, INC., Hsinchu Hsien (TW)

(21) Appl. No.: 14/219,019

(22) Filed: Mar. 19, 2014

(30) Foreign Application Priority Data
Apr. 26, 2013 (CN) 201310149618X

(51) Int. Cl. H01L 33/52; H01L 33/60

(52) U.S. Cl. CPC H01L 33/52; H01L 33/60
USPC 257/98

(57) ABSTRACT

A light emitting diode (LED) package includes a substrate, a pin structure and a reflector formed on the substrate, an LED chip arranged on the pin structure and a first encapsulation layer mixed with phosphor filled in the reflector. The LED chip includes a top surface, a side surface extending downward from the top surface and a bottom surface opposite to the top surface. A bottom end of the first encapsulation layer is located above the top surface of the LED chip. A transparent second encapsulation layer is located below the first encapsulation layer and surrounds the LED die.

### BACKGROUND

1. Technical Field

The disclosure relates to semiconductor structures, and more particularly to a light emitting diode (LED) package with an improved encapsulation structure wherein phosphor filled the encapsulation structure of the LED package can have a high efficiency of excitation.

2. Description of the Related Art

LEDs have low power consumption, high efficiency, quick reaction time, long lifetime, and the absence of toxic elements such as mercury during manufacturing. Due to those advantages, traditional light sources are gradually replaced by LEDs.

A conventional LED package includes an LED die, a reflector receiving the LED die therein, and an encapsulation layer mixed with phosphor filled in the reflector. Light emitted by the LED die excites the phosphor in the reflector to obtain white light radiating out from the LED package. However, most of the light emitted by the LED die is mainly concentrated at a top face of the LED die, which excites a part of the phosphor located over the LED die and in an upper portion of the reflector. The light at a periphery of the LED die is relatively poor and cannot sufficiently excite a part of the phosphor located around the LED die and in a bottom of the reflector. Such that, the exciting efficiencies of the phosphor filled in different parts of the reflector are not uniform, and the whole exciting efficiency of the phosphor is low.

Therefore, it is desirable to provide an LED package with high exciting efficiency of phosphor filled in an encapsulation structure thereof.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present LED package. Moreover, in the drawings, all the views are schematic, and like reference numerals designate corresponding parts throughout the views.

FIG. 1 is a cross-sectional, schematic view of an LED package in accordance with a first exemplary embodiment of the present disclosure.

FIG. 2 is a cross-sectional, schematic view of an LED package in accordance with a second exemplary embodiment of the present disclosure.

### DETAILED DESCRIPTION

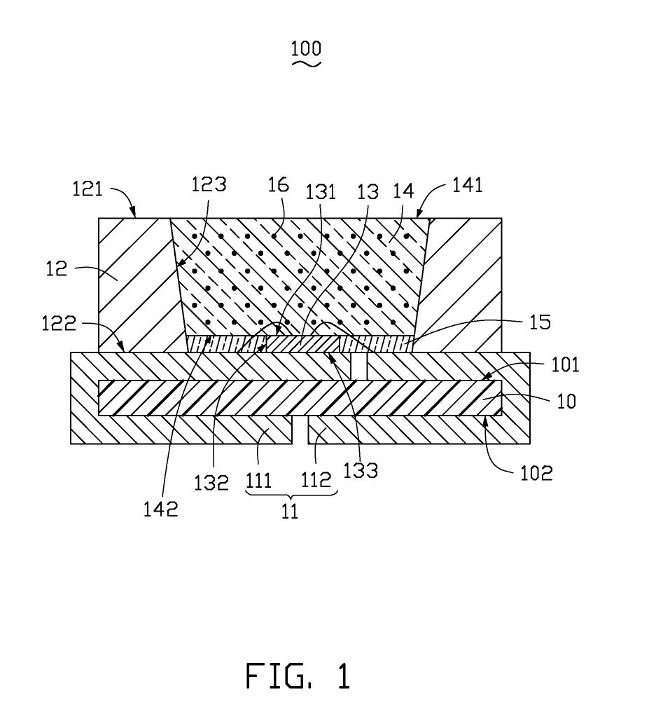

Referring to FIG. 1, an LED package 100 in accordance with a first embodiment is provided. The LED package 100 includes a substrate 10, a pin structure 11 enclosing the substrate therein, an LED die 13 arranged on the pin structure 11, a first encapsulation layer 14 and a second encapsulation layer 15, and a reflector 12 arranged on the substrate 10 and receiving the LED die 13 and the first encapsulation layer 14 and the second encapsulation layer 15 therein. The first encapsulation layer 14 and the second encapsulation layer 15 consist an encapsulation structure of the LED package 100 of the present disclosure.

Specifically, the substrate 10 is flat and includes a first surface 101 and a second surface 120 opposite to the first surface 101. In this embodiment, the substrate 10 is an electrically insulated plate, which is made of, for example, ceramic.

The pin structure 11 includes a first electrode 111 and a second electrode 112. Each of the first electrode 111 and the second electrode 112 is U-shaped and extends from the first surface 101 to the second surface 102 from opposite sides of the substrate 10.

A cross-sectional view of the reflector 12 is hollow and rectangular. The reflector 12 includes a top surface 121 and a bottom surface 122 opposite to the top surface 121. A recess 123 is defined in a center of the reflector 12 by penetrating the top surface 121 and the bottom surface 122. The LED die 13 is received in the recess 123. A width of the recess 123 gradually decreases along a direction from the top surface 121 to the bottom surface 122. High reflective materials could be also arranged at an inner surface of the reflector 12 defining the recess 123. In this embodiment, the reflector 12 and the substrate 10 are separately formed and then connected together. Alternatively, the reflector 12 and the substrate 10 can be integrally formed as a single piece.

The LED die 13 is arranged at one end of the first electrode 111. The LED die 13 includes a top surface 131 and a side surface 132 extends downwardly from a periphery of the top surface 131. In this embodiment, the LED die 13 is a chip emitting blue light. The LED die 13 is electrically connected with the first electrode 111 and the second electrode 112 via wires (not labeled). Alternatively, the LED die 13 could also be arranged on the pin structure 11 via flip chip method.

The first encapsulation layer 14 is filled in the recess 123. A top end 141 of the first encapsulation layer 14 is coplanar with the top surface 121 of the reflector 12. A bottom end 142 of the first encapsulation layer 14 is located over the LED die 13 and a central portion of the bottom end 142 abuts the top surface 131 of the LED die 13.

The first encapsulation layer 14 is made of transparent material with phosphor 16 filled therein. The transparent material can be chosen from transparent resin, silicone, glass or plastic. In this embodiment, the phosphor 16 is yellow phosphor. Blue light emitted from the top surface 131 of the LED die 13 excites the yellow phosphor 16 to emit yellow light which mixes with the blue light to obtain white light. The white light radiates out of the LED package 100 from the top end 141 of the first encapsulation layer 14. Alternatively, the phosphor 16 could also contain red phosphor and green phosphor to enable the resulted white light to have a better color rendering capability.

The second encapsulation layer 15 is filled in the recess 123. The second encapsulation layer 15 is arranged at a periphery of the LED die 13 and engages the side surface 132 thereof. A top surface of the second encapsulation layer 15 is coplanar with the top surface 131 of the LED die 13 and contacting the bottom end 142 of the first encapsulation layer 14. The second encapsulation 15 is made of transparent silicone, resin, glass or plastic only, without any phosphor therein.

A height of the second encapsulation layer 15 is equal to that of the LED die 13. In this embodiment, the height of the second encapsulation layer 15 is about 200 micrometers. Accordingly, the first encapsulation layer 14 is raised by the second encapsulation layer 15 and located above the top surface 131 of the LED die 13, whereby almost all of the phosphor 16 is in a direct radiation range of the LED die 13 in which most of the light from the LED die 13 is concentrated. Blue light with high brightness emitted from the top surface 131 of the LED die 13 directly excite most of the phosphor 16 in the first encapsulation layer 14 to generate yellow light. Only a relatively small part of the phosphor 16 is exited by the blue light emitted from the top surface 131 and reflected by the reflector 12 and the blue light emitted from the side surface 132 of the LED die 13 which has a low brightness and enters the second encapsulation layer 15 firstly and then enters the first encapsulation layer 14 directly or is reflected by the reflector 12 to enter the first encapsulation layer 14. Accordingly, the phosphor 16 can generate sufficiently intensive yellow light to mix with the blue light to efficiently obtain white light.

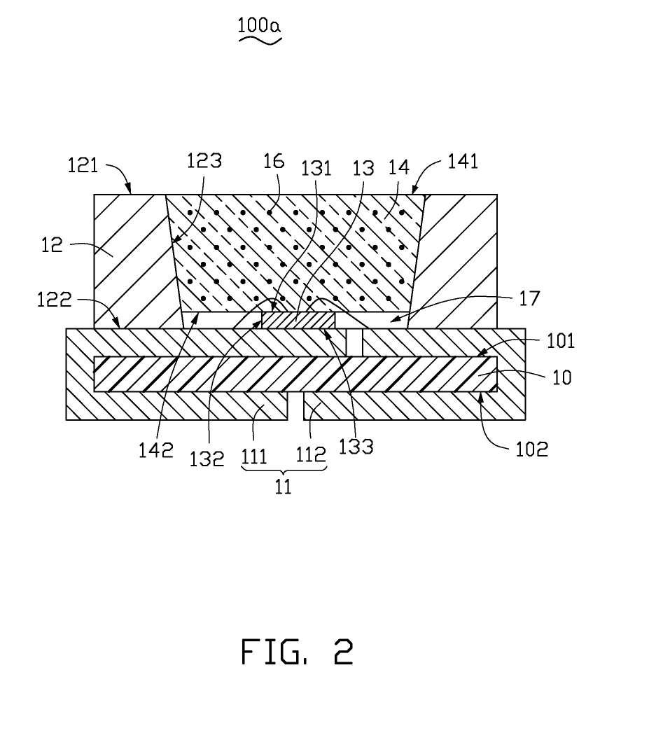

Referring to FIG. 2, an LED package 100a in accordance with a second embodiment is provided. The LED package 100a is similar to the LED package 100. The difference is that the LED package 100a merely includes the first encapsulation layer 14 only. The first encapsulation layer 14 alone consists of the encapsulation structure of the LED package 100a. A part of the bottom end 142 of the first encapsulation layer 14 without contacting the LED die 13 is spaced from the pin structure 11 to form a void gap 17. Blue light radiates from the side surface 132 of the LED die enters the gap 17 firstly, and then enters the first encapsulation layer 14 directly or is reflected by the reflector 12 to enter the first encapsulation layer 14 to excite the phosphor 16 mixed in the first encapsulation layer 14.

Alternatively, the bottom end 142 of the first encapsulation layer 14 could also be located above and spaced from the top surface 131 of the LED die 13. Preferably, the first encapsulation layer 14 mixed with phosphor 16 is entirely located in a direct light radiating range of the LED die 13, and all of the phosphor 16 mixed in the first encapsulation layer 14 could be directly excited by the light from top surface 131 of the LED die 13. Alternatively, the bottom end 142 of the first encapsulation layer 14 without contacting the top surface 131 of the LED die 13 could also be lower than the top surface 131 of the LED die 13 but higher than a bottom surface 133 of the LED die 13. Such that, the exciting efficiency of the phosphor 16 can still be enhanced.

Compared to the traditional LED package, the LED package 100 (100a) includes a first encapsulation layer 14 evenly mixed with phosphor 16, and the bottom end 142 of the first encapsulation layer 14 is higher than a bottom surface 133 of the LED die 13. Light with high brightness radiating out from the top surface 131 of the LED die 13 can adequately impinge the phosphor 16 mixed in the encapsulation layer 14 to obtain white light, and a quantity of a part of phosphor 16 arranged at a bottom of the recess 123 defined by the reflector 12 which can not be effectively excited by the blue light from the LED die 13 is sufficiently reduced, whereby the exciting efficiency of phosphor mixed in the encapsulation structure of the LED package 100 (100a) is enhanced.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A light emitting diode (LED) package, comprising:
a substrate;
a pin structure arranged on the substrate;
a reflector arranged on the substrate;
an LED die arranged on the pin structure and received in the reflector, the LED die comprising a top surface, a side surface extending downward from the top surface, and a bottom surface opposite to the top surface; and
a first encapsulation layer mixed with phosphor filled in the reflector, a bottom end of the first encapsulation layer being located above the bottom surface of the LED die.

2. The LED package of claim 1, wherein a part of the bottom end of the first encapsulation layer engages the top surface of the LED die.

3. The LED package of claim 2, wherein an area of the bottom end of the first encapsulation layer without engaging the top surface of the LED die is spaced from the pin structure to form a void gap.

4. The LED package of claim 2 further comprising a second encapsulation layer, wherein the second encapsulation layer is arranged on the substrate and at a periphery of the LED die to engage the side surface thereof, a top end of the second encapsulation layer engaging an area of the bottom end of the first encapsulation layer without contacting the top surface of the LED die, the second encapsulation layer being transparent and without any phosphor therein.

5. The LED package of claim 4, wherein a height of the second encapsulation layer along a height direction of the LED package is equal to that of the LED die.

6. The LED package of claim 5, wherein a height of the second encapsulation layer is 200 micrometers along the height direction.

7. The LED package of claim 4, wherein a height of the second encapsulation layer along a height direction of the LED package is smaller than that of the LED die, and a top end of the second encapsulation layer is lower than the top surface of the LED die.

8. The LED package of claim 4, wherein a height of the second encapsulation layer along a height direction of the LED package is greater than that of the LED die, and a top end of the second encapsulation layer is higher than the top surface of the LED die.

9. The LED package of claim 4, wherein the reflector comprises a bottom surface near to the substrate and a top surface opposite to the bottom surface, the reflector defining a recess penetrating the top surface and the bottom surface, the LED die being received in the recess, both the first encapsulation layer and the second encapsulation layer being filled in the recess, a top end of the first encapsulation layer is coplanar with the top surface of the reflector.

10. The LED package of claim 1, wherein the pin structure comprises a first electrode and a second electrode spaced from the first electrode, the LED die being arranged on an end of the first electrode near to the second electrode, the LED die being electrically connected to the first electrode and the second electrode via wires.

11. An LED package comprising:
a substrate;
an electrode structure mounted on the substrate;
an LED die mounted on the electrode structure; and
an encapsulation structure having phosphor therein;
wherein light from the LED die excites the phosphor to generate light having a color different from that of the light from the LED die; and
wherein the phosphor is totally located above a top surface of the LED die.

12. The LED package of claim 11, wherein the encapsulation structure comprises a first encapsulation layer located over the LED die and a second encapsulation layer located below the first encapsulation layer and surrounding the LED die, the phosphor being all in the first encapsulation layer and the second encapsulation layer being transparent, a bottom of the first encapsulation layer engaging with a top of the LED die and a top of the second encapsulation layer.

13. The LED package of claim 11, wherein the encapsulation structure comprises a first encapsulation layer only, which is located over the LED die, the phosphor being all in the first encapsulation layer and the first encapsulation layer being spaced from the substrate by a void gap, a bottom of the first encapsulation layer engaging a top of the LED die.
